(19) United States
(12) Patent Application Publication
(10) Pub. No.: US 2026/0178810 A1
(43) Pub. Date: Jun. 25, 2026

(54) VEHICLE DYNAMICS CONTROL AND VEHICLE DYNAMICS CONTROL SYSTEM FOR A VEHICLE

(71) Applicant: Robert Bosch GmbH, Stuttgart (DE)

(72) Inventors: Fabian Schnelle, Tamm (DE); Markus Beisswenger, Schwaebisch Hall (DE); Markus Glaser, Sindelfingen (DE)

(21) Appl. No.: 19/127,475

(22) PCT Filed: Jan. 19, 2024
(86) PCT No.: PCT/EP2024/051231

§ 371 Date: May 6, 2025

(30) Foreign Application Priority Data
Jan. 25, 2023 (DE) 10 2023 200 563.8

(51) Int. Cl. G06F 30/367; B60W 10/08

(52) U.S. Cl. CPC G06F 30/367; B60W 10/08

(57) ABSTRACT

A vehicle dynamics control for a vehicle. A feedforward algorithm of the vehicle dynamics control is parameterized using a model behavior of a virtual analogous model of the vehicle. The model behavior of the analogous model is compared with a real-life behavior of the vehicle, and the analogous model is adapted when the model behavior deviates from the real-life behavior.

### FIELD

The present invention relates to a vehicle dynamics control for a vehicle, to a corresponding vehicle dynamics control system, and to a corresponding computer program product.

### BACKGROUND INFORMATION

A vehicle can have a vehicle dynamics control system. The vehicle dynamics control system can actuate actuators of the vehicle in order to influence the vehicle dynamics of the vehicle. For this purpose, the vehicle dynamics control system can read in sensor signals from, for example, inertial sensors of the vehicle and, for example in response to a vehicle swerving as reflected in the sensor signals, actuate the actuators in order to counteract the swerving.

The inertia of the vehicle leads to a certain time delay from occurring events, since the swerving can only be reflected in the sensor signals when a corresponding movement of the vehicle actually takes place.

To counteract this, the vehicle dynamics control system can have a model-based feedforward control. Inputs from a driver of the vehicle are processed by a virtual analogous model of the vehicle, and the actuators are actuated on the basis of a calculated reaction of the model. The model can predict that the vehicle will likely reach a limit range given predetermined inputs. The vehicle dynamics control system can therefore pre-control actuators before the swerving is detectable in the sensor signals.

European Patent Application No. EP 2 832 599 A1 describes a method and a device for operating a vehicle.

### SUMMARY

Against this background, the approach presented here according to the present invention provides a vehicle dynamics control for a vehicle, a corresponding vehicle dynamics control system, and a corresponding computer program product. Advantageous developments and improvements of the present invention emerge from the description and the rest of the disclosure herein.

A conventional virtual analogous model cannot fully represent the behavior of a real vehicle because the conventional analogous model is preconfigured for all vehicles of a vehicle type or vehicle configuration. Individual differences between essentially identical vehicles, such as different tires and/or different loads, thus cannot be taken into account.

In the approach presented here according to the present invention, an actual behavior of the individual vehicle during the journey is evaluated and compared with a model behavior of the analogous model. The individual characteristics of the vehicle are reflected in the individual actual behavior. If there are deviations between the actual behavior and the model behavior, the analogous model is changed to minimize these deviations.

By means of the approach presented here according to the present invention, the analogous model can represent the individual characteristics of the vehicle and thus predict the behavior of the vehicle with a high degree of accuracy. This expected behavior will reflect the actual behavior very well, even in the limit range of the vehicle dynamics. As a result, the expected behavior can advantageously be used to parameterize a feedforward algorithm of a vehicle dynamics control.

According to an example embodiment of the present invention, a vehicle dynamics control for a vehicle is provided, wherein a feedforward algorithm of the vehicle dynamics control is parameterized using a model behavior of a virtual analogous model of the vehicle, wherein the model behavior of the analogous model is compared with a real-life behavior of the vehicle, and the analogous model is adapted if the model behavior deviates from the real-life behavior.

Ideas for embodiments of the present invention may be considered, inter alia, as being based on the concepts and findings described below.

A vehicle dynamics control for a vehicle can be carried out by a vehicle dynamics control system of the vehicle. The vehicle dynamics control can in particular influence the lateral dynamics of the vehicle. The lateral dynamics determine, for example, a cornering behavior or a yaw behavior of the vehicle. The vehicle dynamics control system can comprise a feedforward algorithm and a feedback controller. The vehicle dynamics control system can act on at least one actuator of the vehicle that influences the lateral dynamics. The actuator can, for example, be a braking system of the vehicle. The actuator can also be a rear axle steering system. The actuator can also be a controllable differential. These actuators can influence a yaw rate of the vehicle.

According to an example embodiment of the present invention, the feedforward algorithm and the feedback controller can each send control commands to at least one actuator. The feedforward algorithm acts proactively, while the feedback controller acts reactively. The feedforward algorithm therefore intervenes before something happens so that it does not happen. The feedback controller intervenes if it has happened.

In order to intervene proactively, the feedforward algorithm requires prior knowledge about an expected driving behavior of the vehicle on an input, such as a steering input, acceleration input and/or deceleration input. This prior knowledge is represented in a virtual analogous model of the vehicle. The analogous model processes the same inputs as the vehicle and represents the driving behavior expected on the basis of these inputs in a model behavior as the output. Parameters of the model behavior can be input variables of the feedforward algorithm.

Here, the model behavior is compared with the actual behavior of the vehicle in response to these inputs. The actual behavior is referred to as real-life behavior. If the real-life behavior deviates from the model behavior, the analogous model is changed until the real-life behavior and the model behavior substantially agree.

According to an example embodiment of the present invention, the real-life behavior can be observed using at least one current measured variable detected on the vehicle. The real-life behavior can be observed by an observer of the vehicle dynamics control system. A measured variable can, for example, be represented in a sensor signal of a sensor of the vehicle. The measured variable can be, for example, a yaw rate, a steering angle or a lateral acceleration. The real-life behavior can be recognized in particular by using a plurality of measured variables. The at least one measured variable can be evaluated by the observer. The observer can recognize the real-life behavior on the basis of the at least one measured variable. The real-life behavior is influenced by actual vehicle states. The observer can observe the at least one measured variable and the input in order to recognize the actual vehicle states. A vehicle state can be, for example, a center of gravity of the vehicle, a payload of the vehicle, a tire state of the vehicle or a road state beneath the vehicle. The actual vehicle states can be compared with model states of the analogous model, and deviations between the vehicle states and the model states can be output as state corrections.

According to an example embodiment of the present invention, the vehicle states can be recognized by comparing the at least one measured variable with an ideal value representing an ideal behavior. With the ideal behavior, an ideal vehicle drives figuratively as if it were on rails in response to the input. The ideal behavior is unattainable in reality.

According to an example embodiment of the present invention, at least one model state of the analogous model can be adapted using a state correction for the model state. Adaptable model states can be predefined. Adaptable model states can be a selection of the model states of the analogous model. A change direction of the state correction can be predetermined by an observed deviation of the real-life behavior from the model behavior.

According to an example embodiment of the present invention, a maximum of two model states can be adapted simultaneously. A limitation to two simultaneous changes means that a clear relationship between cause and effect can be observed. If more than two model states change, it is no longer possible to clearly determine which change led to which effect. If there are more than two adaptable model states, the model states to be adapted can be cycled through iteratively.

The state correction can be limited to a predefined value range around the current model state. The state correction can be limited to a limited state correction. The limitation can be made in a limiter of the vehicle dynamics control system. The limitation means that excessive changes in the model states can be prevented. Larger changes can be made step by step. After each step-by-step change of the model states, the new model behavior can be compared with the real-life behavior in order to check the success of the change.

According to an example embodiment of the present invention, the value range can be set depending on a driving situation of the vehicle. The value range can be limited, in particular when the vehicle approaches a limit range. If the vehicle dynamics control system intervenes to stabilize the vehicle, the state corrections can be omitted. As a result, larger state corrections can only be made far away from the limit range. It can thus be ensured that a state correction does not change the model behavior into a critical or unstable range.

The state correction can be limited to physically reasonable values. The reasonable values can be based on prior knowledge. The reasonable values can be limited by reasonable limit values. The limit values can ensure that the model behavior remains outside the critical or unstable range.

The method is preferably computer-implemented and can be implemented, for example, in software or hardware or in a mixed form of software and hardware, for example in a driver assistance system.

The approach presented here according to the present invention furthermore provides a vehicle dynamics control system for a vehicle, the vehicle dynamics control system being designed to carry out, actuate or implement the steps of a variant of the method of the present invention presented here in corresponding devices.

The vehicle dynamics control system can be an electrical device comprising at least one computing unit for processing signals or data, at least one memory unit for storing signals or data, and at least one interface and/or communication interface for reading in or outputting data embedded in a communication protocol. The computing unit can, for example, be a signal processor, a so-called system ASIC, or a microcontroller for processing sensor signals and outputting data signals depending on the sensor signals. The memory unit can, for example, be a flash memory, an EPROM, or a magnetic memory unit. The interface can be designed as a sensor interface for reading in the sensor signals from a sensor and/or as an actuator interface for outputting the data signals and/or control signals to an actuator. The communication interface can be designed to read in or output the data in a wireless and/or wired manner. The interfaces may also be software modules that are present, for example, on a microcontroller in addition to other software modules.

A computer program product or a computer program having program code that can be stored on a machine-readable carrier or storage medium, such as a semiconductor memory, a hard disk memory, or an optical memory, and that is used for carrying out, implementing, and/or controlling the steps of the method according to one of the embodiments of the present invention described above, in particular when the program product or program is executed on a computer or a device, is advantageous as well.

It is pointed out that some of the possible features and advantages of the present invention are described herein with reference to different example embodiments. A person skilled in the art recognizes that the features of the control unit and of the method can be suitably combined, adapted or replaced in order to arrive at further embodiments of the present invention.

### BRIEF DESCRIPTION OF THE DRAWINGS

Example embodiments of the present invention are described below with reference to the figures, and neither the figures nor the description should be construed as limiting the present invention.

FIG. 1 shows a block diagram of a vehicle dynamics control system according to an exemplary embodiment of the present invention.

FIG. 2 shows a detail of a vehicle dynamics control system according to an exemplary embodiment of the present invention.

The figures are merely schematic and not true to scale. Identical reference signs refer to identical or identically acting features.

### DETAILED DESCRIPTION OF EXAMPLE EMBODIMENTS

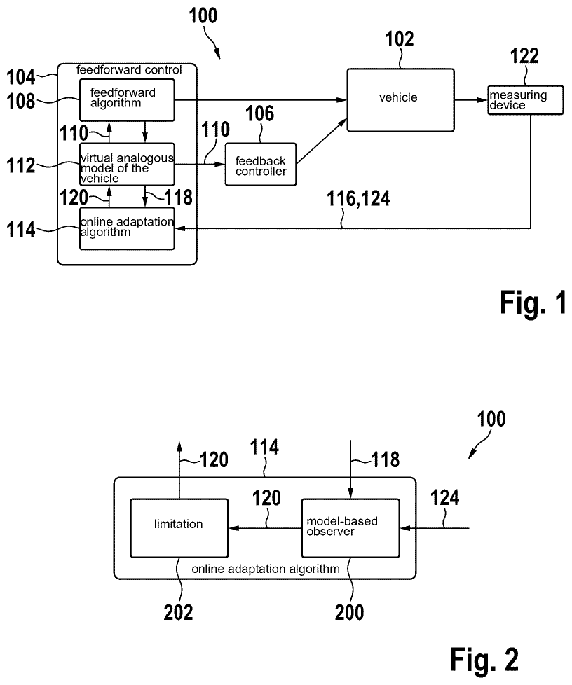

FIG. 1 shows a block diagram of a vehicle dynamics control system 100 of a vehicle 102. The vehicle dynamics control system 100 acts on at least one actuator of the vehicle 102 in order to influence a yaw rate of the vehicle 102. The actuator can be, for example, a braking system of the vehicle 102, a steerable rear axle of the vehicle or an actuatable torque vectoring axle of the vehicle.

The vehicle dynamics control system 100 has a feedforward control 104 and a feedback controller 106. Both the feedforward control 104 and the feedback controller 106 generate control commands for the actuator in order to influence a yaw rate. A feedforward algorithm 108 of the feedforward control 104 acts in a predictive manner and proactively outputs control commands in order to prevent undesirable driving behavior of the vehicle 102. Should the vehicle nevertheless exhibit undesirable driving behavior, the feedback controller 106 outputs control commands in order to counteract the undesirable driving behavior. In order to adapt the control commands to the vehicle 102 as well as possible, the feedforward algorithm 108 and the feedback controller 106 are parameterized by an online adaptation algorithm 114 using a model behavior 110 of a virtual analogous model 112 of the vehicle 102.

In the approach presented here, the model behavior 110 of the analogous model 112 is compared with a real-life behavior 116 of the vehicle 102. On the basis of a result of the comparison, the analogous model 112 is adapted to bring the model behavior 110 as close as possible to the real-life behavior 116.

In one exemplary embodiment, the online adaptation algorithm 114 reads in at least one model state 118 of the analogous model 112 and, on the basis of the result of the comparison, outputs a state correction 120 for this model state 118 in order to adapt the analogous model 112.

In one exemplary embodiment, at least one measured variable 124 detected on the vehicle 102 by a measuring device 122 is evaluated by the online adaptation algorithm 114 in order to recognize the real-life behavior 116. The model behavior 110 can be derived from output variables of the analogous model 112 and/or the model states 118.

FIG. 2 shows a detail of a vehicle dynamics control system 100 according to an exemplary embodiment. The detail shows the online adaptation algorithm 114 from FIG. 1. Here, the online adaptation algorithm 114 has a model-based observer 200 for observing the measured variables 124 and model states 118. The observer 200 determines the state correction 120 from the observed measured variables 124 and observed model states 118.

In one exemplary embodiment, the online adaptation algorithm 114 has a limitation 202. The limitation 202 reads in the unlimited state correction 120 and limits the state correction 120 in order to prevent excessive changes to the analogous model.

In one exemplary embodiment, the unlimited state correction 120 is limited to realistic values in order to obtain the limited state correction 120.

In one exemplary embodiment, the limitation 202 limits the state correction 120 depending on a current stability state of the vehicle. In this way, state corrections 120 are at least limited when the vehicle is in an unstable driving state. The limitation 202 therefore limits the state correction 120 when the vehicle dynamics control system 100 is active.

Possible embodiments of the present invention are summarized again below or described using slightly different words.

An online adaptation of model-based vehicle dynamics controls for increasing performance and robustness is presented.

Today, vehicle dynamics control systems for ensuring vehicle stability typically use a model-based approach with fixed parameters for controlling lateral dynamics. As a rule, the parameters are determined once and then stored permanently in the control unit code. This means a permanently defined or applied model behavior. Typical vehicle dynamics models are linear and nonlinear single-track models with the states yaw rate and slip angle.

The vehicle dynamics models have a two-degree-of-freedom structure with feedforward control (FF) and feedback control (FB), as described, for example, in European Patent Application No. EP 2 832 599 A1. The control loop is typically closed via the yaw rate. Deviations between reality and model always occur. Typical reasons for this are, for example, tire variations (wear, model, summer/winter tires, . . . ), loading variations (empty, full, high center of gravity, . . . ), road disturbances, model inaccuracies (dynamics not taken into account, unknown friction coefficient) and road inclinations in the lateral direction. These uncertainties lead to deviations between the target and actual yaw rate.

This can lead to miscorrections via the feedback control path. This is compensated for by increased correction thresholds. This can lead to delayed correction and thus reduced performance in use. In addition, the feedforward control path can no longer fully ensure the control behavior because the model and thus the states do not match reality.

The approach presented here extends the vehicle dynamics control described in European Patent Application No. EP 2 832 599 A1 by adding the possibility of real-time adaptation to the current conditions. Inaccuracies of the system to be controlled (e.g., tires, aging, loading) are taken into account. This results in an increased model validity in comparison with European Patent Application EP 2 832 599 A1 and thus an improved control behavior via the feedforward control path.

The approach presented here allows targeted, early intervention by the feedforward control in order to impose a desired driving behavior. This makes the feedforward control much more effective. Harsh, uncomfortable feedback control interventions are prevented. Furthermore, there is increased robustness against miscorrections during normal driving.

Due to the interventions by the feedforward control, no feedback interventions are required because the actual and target yaw rates match. The hardware load can thus be reduced. Furthermore, correction thresholds can be reduced, which leads to greater performance in use.

In the approach presented here, the real-time adaptation of the vehicle model to reality is carried out via a model-based observer approach. The observer continuously compares the measurable states of the real vehicle with the states of the vehicle model and, on the basis of this and of physical models, estimates the level of disturbances to the states (beta, dPsi) and corrects them so that they better match the real vehicle behavior. As a result, the model behavior is adapted to the actual behavior in real time. The effect of the sum of all uncertainties in the model is corrected.

The observer may only move within the framework of previously defined uncertainties. These are based on physical estimates of the influence of a wide variety of disturbances on the dynamics, such as the influence of tire variations. These estimates apply to the linear range, i.e., with large slip angles they automatically become very small. As a result, each project can individually set which disruptions occur and to what extent. During normal driving, the observer thus always remains within the defined uncertainty band and can fully correct the states. This means that no control deviation can occur, miscorrections are avoided, and modeled states remain valid for longer, i.e., the feedforward control can impose the desired control behavior for longer.

In use, the disturbances caused by dynamic effects can become so large that they are significantly larger than the uncertainty band. Then the disturbances can be limited. The limitation can go so far that no disturbance at all is permitted in use. Thus, the application of the target behavior (target yaw rate) is still possible, since it is not influenced by the observer approach. Application via feedback is still possible.

In the approach presented here, the adaptation is carried out much more rapidly than conventional parameter adaptations (e.g., vch). The influence of road disturbances such as potholes, bumps and friction coefficient changes on the vehicle can thus be immediately recognized and modeled.

The approach presented here describes an online adaptation algorithm that adapts the vehicle model to the real vehicle in real time using a model-based observer approach. On the one hand, the measured variables such as yaw rate, steering angle and lateral acceleration and, on the other hand, the states of the feedforward control vehicle model are used for the algorithm. On the basis of this information, the algorithm calculates the appropriate state corrections for the vehicle model so that it matches the current environment better.

The algorithm consists of two blocks. A first block is the model-based observer. The second block is the limitation calculation.

In the model-based observer, a calculation rule is derived on the basis of the physical equations underlying the vehicle and compares the model states with the measured variables and calculates the necessary corrections in order to adapt the model states to the actual states.

In the limitation calculation, a band is calculated in real time using previously defined uncertainties and physical estimates within which band the disturbance variables and thus the state corrections can vary at most. This band also depends on the extent to which the vehicle is in the use case. This ensures that the algorithm only corrects and ensures robustness in the non-use case and still allows application of the target behavior and the feedback in the use case.

Blocks 104 to 106 represent the standard control loop structure as also described in European Patent Application No. EP 2 832 599 A1. Block 114 relates to the extension described here for online adaptation of the vehicle model. In detail, block 114 consists of a model-based observer 200 and a limitation calculation 202.

The approach presented here allows the target yaw rate to be adjusted directly (immediately after the uncertainty is imposed) when physical vehicle parameters vary.

Finally, it should be pointed out that terms like “having,” “comprising,” etc. do not exclude other elements or steps and terms like “a” or “an” do not exclude a plurality. Reference signs are not to be considered as limiting.

1-10. (canceled)

11. A method of vehicle dynamics control for a vehicle, comprising the following steps:
parameterizing a feedforward algorithm using a model behavior of a virtual analogous model of the vehicle;
comparing the model behavior of the analogous modelwith a real-life behavior of the vehicle; and
adapting the analogous model when the model behavior deviates from the real-life behavior.

12. The method according to claim 11, wherein the real-life behavior is observed using at least one current measured variable detected on the vehicle.

13. The method according to claim 11, wherein at least one model state of the analogous model is adapted using a state correction for the model state.

14. The method according to claim 13, wherein a maximum of two model states are adapted simultaneously.

15. The method according to claim 13, wherein the state correction is limited to a predefined value range around the model state.

16. The method according to claim 15, wherein the value range is set depending on a driving situation of the vehicle.

17. The method according to claim 13, wherein the state correction is limited to physically reasonable values.

18. A vehicle dynamics control system, the vehicle dynamics control system being configured to execute and/or implement and/or actuate a method of vehicle dynamics control, the method comprising:
parameterizing a feedforward algorithm using a model behavior of a virtual analogous model of the vehicle;
comparing the model behavior of the analogous modelwith a real-life behavior of the vehicle; and
adapting the analogous model when the model behavior deviates from the real-life behavior.

19. A non-transitory machine-readable storage medium on which is stored a computer program for vehicle dynamics control, the computer program, when executed by a processor, causing the processor to perform the following steps:
parameterizing a feedforward algorithm using a model behavior of a virtual analogous model of the vehicle;
comparing the model behavior of the analogous modelwith a real-life behavior of the vehicle; and
adapting the analogous model when the model behavior deviates from the real-life behavior.
